(19) United States
(12) Patent Application Publication
(10) Pub. No.: US 2008/0043543 A1
(43) Pub. Date: Feb. 21, 2008

(54) Method for manufacturing, writing method and reading non-volatile memory

(75) Inventors: Wei-Chung Chen, Chiayi (TW); Ta-Neng Ho, Chungho city (TW); Ti-Wen Chen, Tainan (TW); Wei-Ming Chen, Hsinchu (TW)

Correspondence Address: BACON & THOMAS, PLLC, 625 SLATERS LANE, FOURTH FLOOR, ALEXANDRIA, VA, 22314, US

(73) Assignee: Macronix International Co., Ltd., Hsinchu (TW)

(21) Appl. No.: 11/889,804

(22) Filed: Aug. 16, 2007

(30) Foreign Application Priority Data
Aug. 17, 2006 (TW) 95130275
Mar. 9, 2007 (TW) 96108273

(51) Int. Cl. G11C 7/00; H01L 21/266

(52) U.S. Cl. 365/189.15; 365/189.16; 438/17; 257/E21.346

(57) ABSTRACT

A method of manufacturing, programming and reading a non-volatile memory is provided. First, a to-be-coded memory having a plurality of to-be-coded cells arranged in a array is provided. Next, an implanting resist layer is formed on the to-be-coded memory. Then, a mask is disposed on the to-be-coded memory, wherein the number of the partial to-be-coded cells under the openings of the mask is less than the number of remaining to-be-coded cells. Afterwards, a patterned implanting resist layer is formed according to the mask. Next, the exposed to-be-coded cells are ion-implanted to define a plurality of first cells and second cells, wherein each first cell and each second cell record a second bit state and a first bit state respectively. Then, the to-be-coded memory is inversely defined, such that the first cells and the second cells record the first bit state and the second bit state respectively.

This application claims the benefit of Taiwan Patent Application No. 95130275, filed Aug. 17, 2006, and Taiwan Patent Application No. 96108273, filed Mar. 9, 2007, the contents of which are herein incorporated by reference in its entirety.

### BACKGROUND OF THE INVENTION

1. Field of the Invention

The invention relates in general to a method of manufacturing, writing method and reading a non-volatile memory, and more particularly to a method of manufacturing a non-volatile memory capable of preventing the failure in ion-implantation caused by an external object, and a method of writing and reading the non-volatile memory and capable of reducing the required time for programming the non-volatile memory.

2. Description of the Related Art

With the coming of an electronic age, the demand for data storage medium also increases. Therefore, the semiconductor technology for manufacturing the memory device in a larger quality but at a low cost is continually improved.

Among the memory media manufactured according to the semiconductor technology, the non-volatile memory (NVM) capable of maintaining the memory state of data even when power is off has gained a large extent in the field of application. The non-volatile memory is divided into mask read-only memory (MROM) which defines data by ion-implantation, one-time program (OTP) or multi-time program (MTP) memory such as the basic input/output system (BIOS) of a computer, and multi-time program-erase memory such as flash memory (flash memory). The mask read-only memory and the one-time program memory, having the advantage of simple manufacturing process and large scale production at low cost is suitable to software products requiring a large quantity of duplicated copies such as games.

Let the mask read-only memory be taken for example. The way of program coding is achieved by implanting ions into a pre-manufactured to-be-coded memory. As indicated in FIG. 1, a partial structural diagram of a to-be-coded memory is shown. The to-be-coded memory 10 has a plurality of bit lines 1 disposed in parallel, and a plurality of word lines 2 perpendicular to and disposed above the bit lines 1. A to-be-coded cell 3 disposed at the part of a word line 2 defined between two neighboring bit lines 1 can define various bit states via ion-implantation and record the to-be-coded program on the to-be-coded memory 10.

During ion-implantation, the to-be-coded cells 3 with ion-implantation have to be exposed, and it is possible that the obstruction by a dropped-in object or the misalignment of an ion-implanting resist layer may lead to a failed implantation. Therefore, if the number of the exposed to-be-coded cells increases, the possibility of having defects during ion-implantation also increases.

The current one time program memory and multi-time program memory take a lot of time for electrically programming if there are too many bit state “0” in the data. Furthermore, if there are too many unused memory cells, the program memory also has to spend lots of time for programming the corresponding memory cells to the bit state “0”, wasting both time and costs.

### SUMMARY OF THE INVENTION

The invention is directed to a method of manufacturing non-volatile memory, reading method and writing method which increases the yielding rate of the non-volatile memory by changing the way of implanting the to-be-coded cell. Meanwhile, the application of the programming of the non-volatile memory reduces the required time of production.

According to a first aspect of the present invention, a method of manufacturing a non-volatile memory is provided. First, a to-be-coded memory having a plurality of to-be-coded cells arranged in an array is provided. Next, an implanting resist layer is formed on the to-be-coded memory. Then, a mask is disposed on the to-be-coded memory, wherein the mask has a plurality of openings, the partial to-be-coded cells under the openings are defined as a plurality of second to-be-coded cells, the remaining to-be-coded cells are defined as a plurality of first to-be-coded cells, and the number of the second to-be-coded cells is less than the number of the first to-be-coded cells. Afterwards, a patterned implanting resist layer is formed according to the mask, and the patterned implanting resist layer has a plurality of coding holes for exposing the second to-be-coded cells. Next, the second to-be-coded cells are ion-implanted such that the first to-be-coded cells are defined as a plurality of first cells and the second to-be-coded cells are defined as a plurality of second cells, wherein the first cells and the second cells record a second bit state and a first bit state respectively. Then, the to-be-coded memory is inversely defined, such that the first cells and the second cells record the first bit state and the second bit state respectively.

According to a second aspect of the present invention, another method of manufacturing a non-volatile memory is provided. First, a to-be-coded memory having a plurality of to-be-coded cells arranged in an array is provided. Next, the number of a first bit state and a second bit state in a to-be-coded program is counted. Then, a mask having a plurality of openings is provided if the number of the first bit state is larger than the number of the second bit state, the number of the openings is the same as the number of the second bit state. Next, an implanting resist layer is formed on the to-be-coded memory. Then, a pattern is defined on the implanting resist layer according to the mask to form a patterned implanting resist layer. The patterned implanting resist layer has a plurality of coding holes. The partial to-be-coded cells exposed by the coding holes are defined as a plurality of second to-be-coded cells, and the remaining to-be-coded cells are defined as a plurality of first to-be-coded cells. Next, the second to-be-coded cells are ion-implanted such that the first to-be-coded cells are defined as the first cells and the second to-be-coded cells are defined as the second cells, wherein the first cell and the second cell record a second bit state and a first bit state respectively. Then, the to-be-coded memory is inversely defined, such that the first cells and the second cells record the first bit state and the second bit state respectively.

According to a third aspect of the present invention, a method of writing a non-volatile memory is provided. The writing method comprises the following steps. First, a to-be-coded memory is provided, wherein the memory cells of to-be-coded memory record the first bit state after the memory cells are programmed, and record the second bit state before the memory cells are programmed. Next, the number of the first bit state and the second bit state in the to-be-coded program data is counted. Then, the to-be-coded program data is inversely defined if the number of the first bit state is larger than the number of the second bit state. Next, the to-be-coded program data is written into the to-be-coded memory.

According to a fourth aspect of the present invention, a method of reading a non-volatile memory is provided. The reading method is for reading the to-be-coded memory and comprises the following steps. First, the to-be-coded program data is read. Next, whether the to-be-coded program data is inversely defined is checked. Then, if the to-be-coded program data is inversely defined, then the to-be-coded program data is inversely defined again and outputted.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a partial structural diagram of a to-be-coded memory;

FIG. 2 is a flowchart of a method of manufacturing a non-volatile memory of the invention;

FIG. 2A shows an area distribution of implanted-wafer according to conventional manufacturing method and that according to manufacturing method of the invention;

FIG. 3A is a partial structural diagram of a to-be-coded memory;

FIG. 3B is a top view of a mask;

FIG. 3C is a top view of a to-be-coded memory having a patterned implanting resist layer;

FIG. 3D is a cross-sectional view along a cross-sectional line AA′ of FIG. 3C;

FIG. 4 is a functional block diagram of reading a non-volatile memory of the invention;

FIG. 5A is a circuit diagram of generating a control signal of a first multiplexer of the invention;

FIG. 5B is a circuit diagram of generating a control signal of a second multiplexer of the invention;

FIG. 6 is a functional diagram of the writing and reading circuit of a non-volatile memory of the invention;

FIG. 7 is a flowchart of reading a non-volatile memory of the invention;

FIG. 8 is a flowchart of writing a non-volatile memory of the invention; and

FIG. 9 is another functional diagram of the writing and reading circuit of a non-volatile memory of the invention.

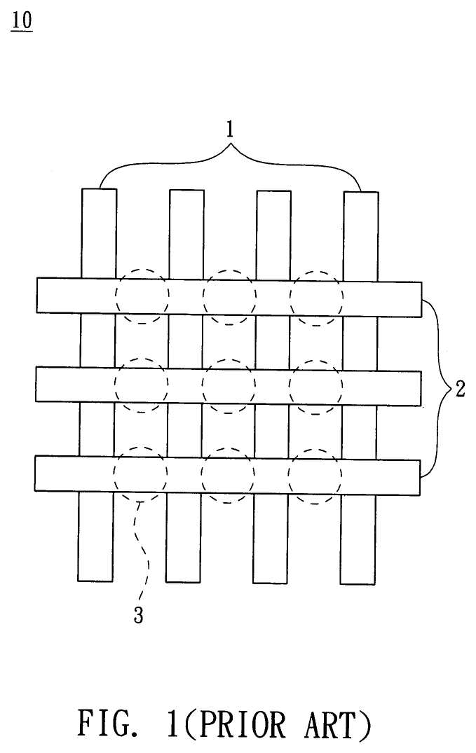

### DETAILED DESCRIPTION OF THE INVENTION

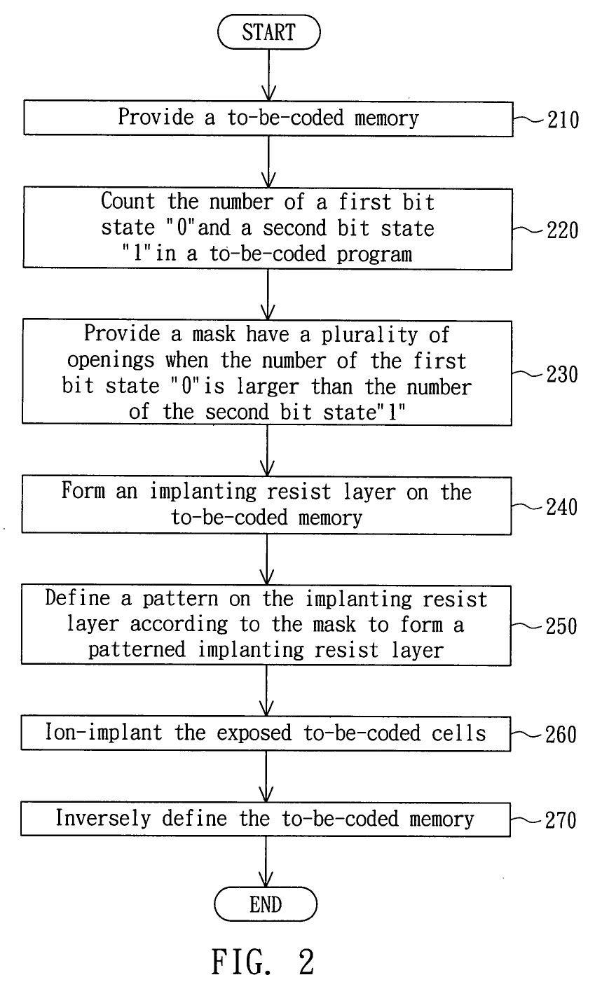

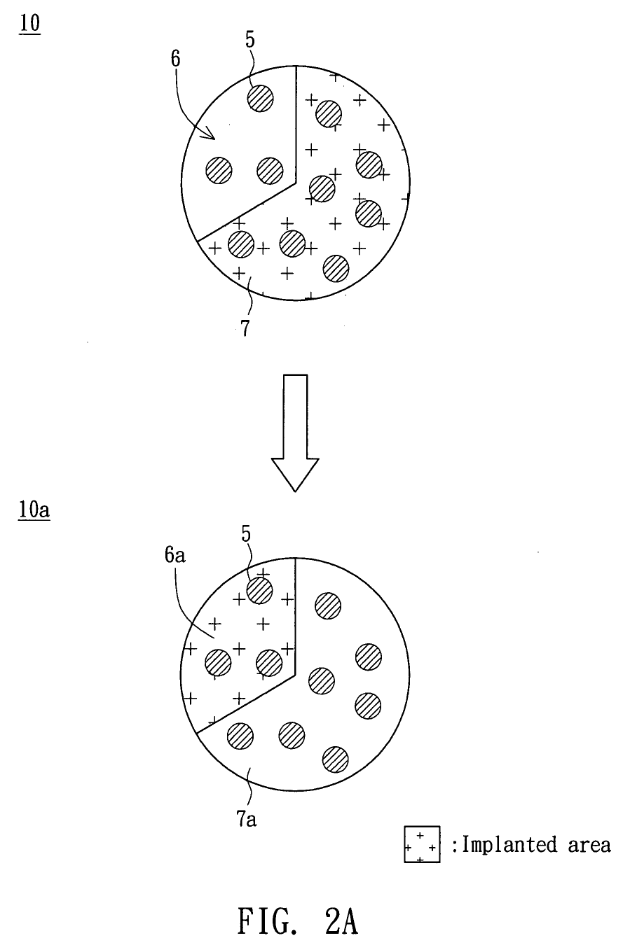

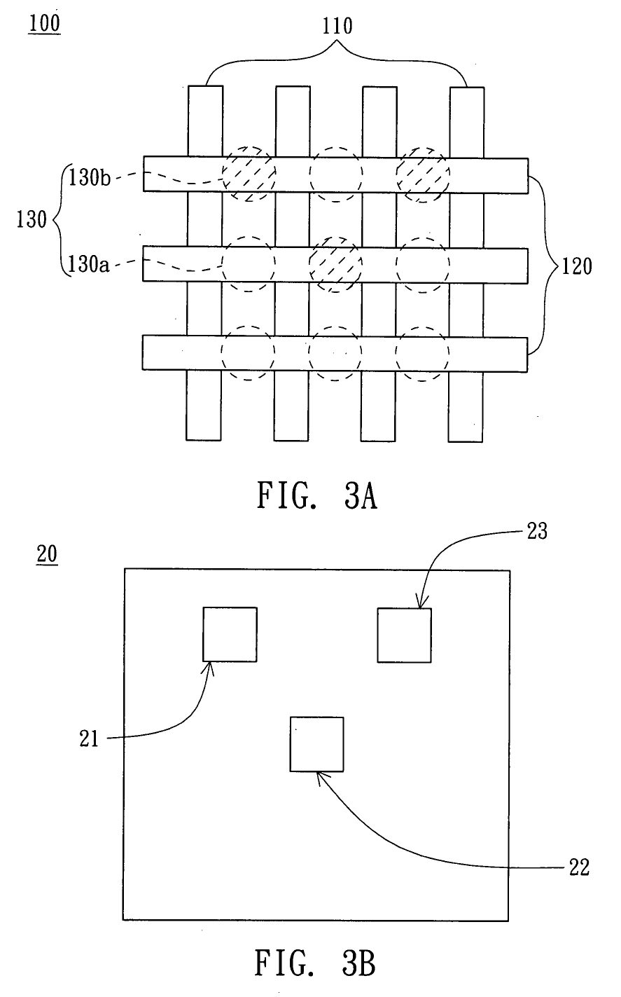

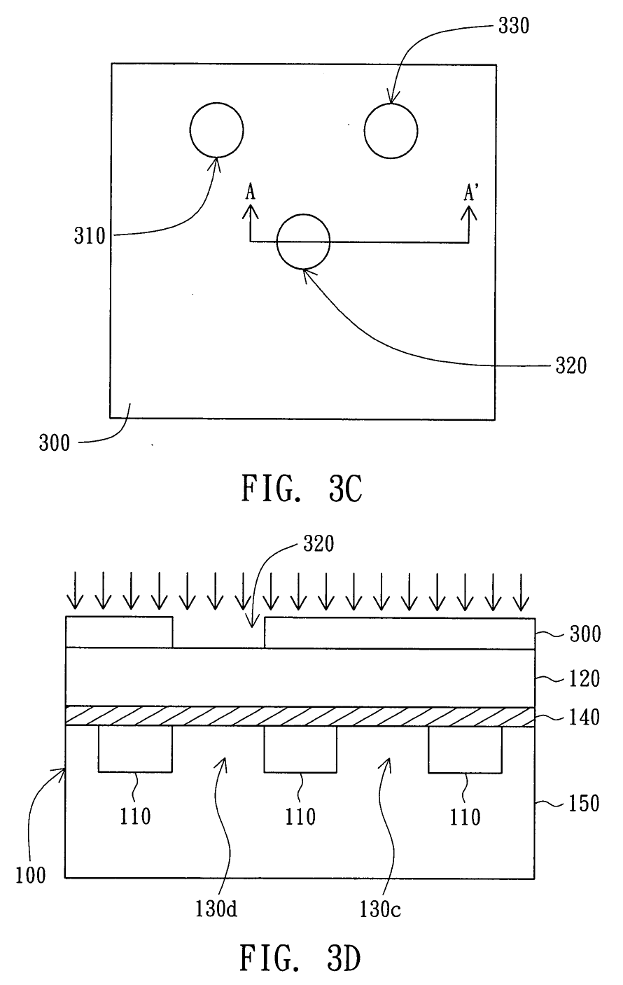

Referring to FIG. 2, a flowchart of a method of manufacturing a non-volatile memory of the invention is shown. Please refer to FIG. 3A˜FIG. 3D. FIG. 3A is a partial structural diagram of a to-be-coded memory. FIG. 3B is a top view of a mask. FIG. 3C is a top view of a to-be-coded memory having a patterned implanting resist layer. FIG. 3D is a cross-sectional view along a cross-sectional line AA′ of FIG. 3C.

First, the method begins at step 210. Referring to FIG. 3A, a to-be-coded memory 100 is provided. The to-be-coded memory 100 has a plurality of bit lines 110 disposed in parallel and a plurality of word lines 120 perpendicular to and disposed above the bit lines 110. A to-be-coded cell 130 is disposed at the part of a word line 120 defined between two neighboring bit lines 110, and there are totally nine to-be-coded cells 130 in the present embodiment of the invention.

Next, the method proceeds to step 220, the number of a first bit state and a second bit state in a to-be-coded program is counted. In the present embodiment of the invention, the first bit state is denoted by “0”, and the second bit state is denoted by “1”; or, the first bit state is denoted by “1”, and the second bit state is denoted by “0”. In the present embodiment of the invention, the number of the first bit state is assumed to be larger than the number of the second bit state, and the first bit state “0” is programmed by ion-implanting the to-be-coded cell 130. In the present embodiment of the invention, the implantation material is exemplified by boron.

Then, the method proceeds to step 230, if the number of the first bit state “0” is larger than the number of the second bit state “1”, that is, if the number of cells with ion-implantation is larger than the number of cells without ion-implantation, a mask is provided. Referring to FIG. 3B, the mask 20 have three openings 21, 22, and 23 respectively corresponding to a to-be-coded cell 130, and the number and the position of the openings are the same as that of the second bit state “1” of the to-be-coded program. That is, ions are implanted to the to-be-coded cells corresponding to the second bit state “1” in the original to-be-coded program, but are not implanted to the to-be-coded cells corresponding to the first bit state “0” in the original to-be-coded program. Referring to the FIG. 3A, the to-be-coded cells 130 under the openings 21, 22, and 23 are defined as second to-be-coded-cells 130b, and the remaining to-be coded cells are defined as to-be-coded-cells 130a.

Next, the method proceeds to step 240, an implanting resist layer is formed on the to-be-coded memory 100.

Then, the method proceeds to step 250, a pattern is defined on the implanting resist layer according to the mask 20 to form a patterned implanting resist layer 300. Referring to FIG. 3C, the patterned implanting resist layer 300 has three coding holes 310, 320, and 330 for exposing the second to-be-coded cells 130b. That is, the cells originally designed to be ion-implanted are masked, and the cells originally designed to be free of ion-implantation are now exposed and ion-implanted.

Next, the method proceeds to step 260. Also, referring to FIG. 3D, a plurality of bit lines 110 are disposed on the base 150 of the to-be-coded memory 100, and the word line 120 and the base 150 are separated by an insulating layer 140. A cell is disposed between two bit lines 110 and located in the channel of the base 150, and ions are implanted into the base 150 by penetrating through the word line 120. Ions are implanted into the exposed second to-be-coded cells 130b such that the first to-be-coded cells 130a without ion-implantation are defined as the first cells 130c, and the second to-be-coded cells 130b with ion-implantation are defined as the second cells 130d. A first current value and a second current value respectively passing through the first cells 130c and the second cells 130d when the first cells 130c and the second cells 130d are turned on are compared with a reference current value to define the first cells 130c and the second cells 130d to have a second bit state “1” and a first bit state “0” respectively. In the present embodiment of the invention, the first current value is larger than reference current value, and the second current value is smaller than reference current value.

Then, the method proceeds step 270. As the defined bit state of a cell is opposite to the bit state expected in the to-be-coded program, the to-be-coded memory is inversely defined. That is, the first cells 130c is defined to record the first bit state if the first current value is larger than the reference current value, and the second cells 130d is defined to record the second bit state if the second current value is smaller than the reference current value, such that the first cells 130c and the second cells 130d record the first bit state “0” and the second bit state “1” respectively. Meanwhile, the bit states recorded in the to-be-coded memory 100 are the same as the bit states in the to-be-coded program.

However, in step 230, if the number of the first bit state “0” is less than the number of the second bit state “1” in the to-be-coded program. That is, if the number of the first bit state “0” requiring ion-implantation to define is less than the number of the second bit state “1” not requiring ion-implantation to define, a second mask is provided. The second mask has a plurality of second openings and the number of the second openings is the same as the number of the first bit state “0”. Next, a pattern is defined on the ion-implanting resist layer by the second mask to form a second patterned ion-implanting resist layer. The second patterned ion-implanting resist layer has a plurality of second coding holes. the partial to-be-coded cells exposed by the second coding holes are defined as third to-be-coded cells, and the remaining to-be-coded cells are defined as fourth to-be-coded-cells. Then, ions are implanted into the exposed third to-be-coded cells 130 such that the third to-be-coded cells with ion-implantation are defined as third cells, and the fourth to-be-coded cells without ion-implantation are defined as fourth cells. A third current value and a fourth current value respectively passing through the third cells and the fourth cells when the third cells and the fourth cells are turned on are compared with a reference current value to define the third cells and the fourth cells to record the first bit state “0” and the second bit state “1” respectively. As the defined bit state of the cells is the same as the bit state required in the to-be-coded program, inverse definition is not required to preceed.

Any one who is skilled in the technology of the invention will understand that the technology of the invention is not limited thereto. For example, in step 260 of comparing the first current value and the second current value, the first cells 130c can be defined to record the second bit state “1” if the first current value is smaller than reference current value, and the second cells 130d can be defined to record the first bit state “0” if the second current value is larger than reference current value. In step 270 of inversely defining the to-be-coded memory 100, the first cells 130c is defined to record the first bit state “0” if the first current value is smaller than reference current value, and the second cells 130d is defend to record the second bit state “1” if the second current value is larger than reference current value. Besides, the first bit state and the second bit state are either “0” or “1”, that is, the first bit state and the second bit state can also be defined as “1” and “0”. Thus the relationship between the first current value, the second current value and the reference current value is not specifically restricted in the invention.

Despite the present embodiment of the invention is exemplified by a mask read-only memory, the application of the invention is not limited thereto. The invention is also applicable to the formation of a contact hole and improves the yielding rate thereof. For the mask memory ion-implanted according to the method of the invention, only a small part of the memory cells are exposed for ion-implantation, hence reducing the probability of errors in data definition caused by the failure in implantation resulted from the obstruction of an external object.

Referring to FIG.2A, an area distribution of implanted-wafer according to conventional manufacturing method and that according to manufacturing method of the invention are compared. The area distribution of the implanted wafer 10 has an region 7 and a region 6. The region 7 occupies 70% area of the wafer and records the bit state “0”. The region 6 occupies 30% area of the wafer and records the bit state “1”. The particles 5 dropped in the implanted wafer uniformly. In the implanted wafer 10, region 7 is implanted and occupies more area, such that the implanted wafer 10 has high failure rate. In the implanted wafer 10a, the region 7a and region 6a record the same bit states as those of the region 7 and region 6, respectively. On the contrary, region 6a is implanted and then inversely defined. Because, the region 6a occupied less area, the implanted wafer 10a can reduce the failure rate.

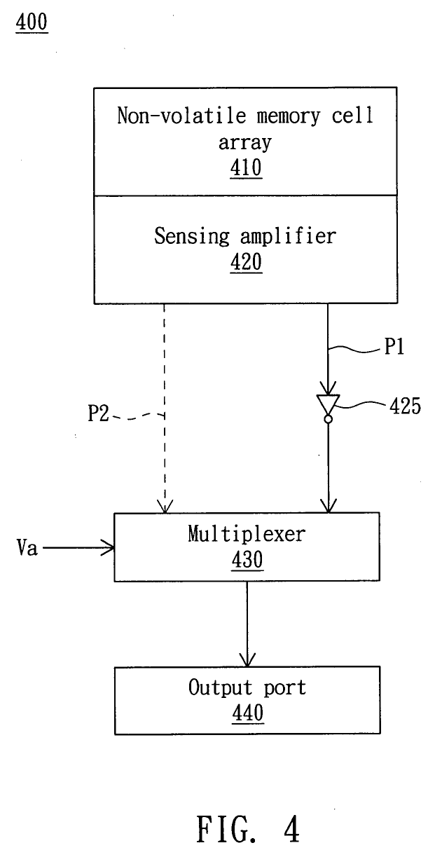

The inverse definition disclosed in step 270 of FIG. 2 can be achieved by ways of circuit design. Referring to FIG. 4, a functional block diagram of reading a non-volatile memory of the invention is shown. The non-volatile memory 400 includes a non-volatile memory cell array 410 and a sensing amplifier 420, wherein the signal outputted from the non-volatile memory cell array 410 is amplified and outputted by the sensing amplifier 420. The non-volatile memory 400 can be a mask read-only memory (mask ROM), a one-time program (OTP) memory, a multi-time program (MTP) memory and a flash memory capable of bearing multi-time program—erase. As indicated in FIG. 4, if the to-be-coded program data is not inversely defined, then the path P2 is taken and the to-be-coded program data passing therethrough is selected by the multiplexer (MUX) 430 according to the original definition of bit state then outputted to the output port 440. If the to-be-coded program data is inversely defined, then the path P1 is taken and the to-be-coded program data is inversely defined by the inverter 425 again, the to-be-coded program data passing through P1 is selected by the multiplexer (MUX) 430 and outputted to the output port 440.

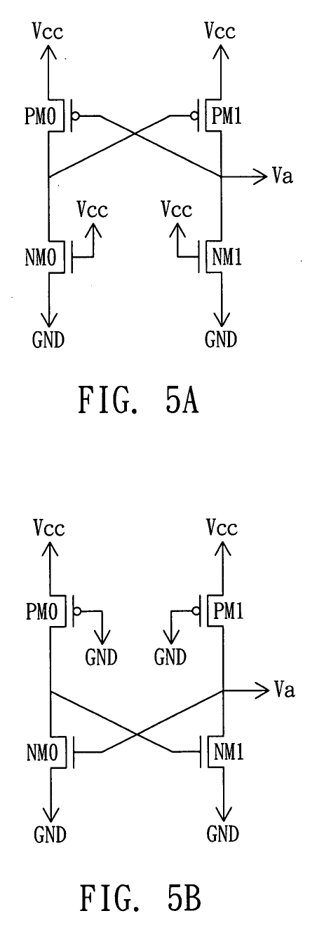

Selecting the path P1 or the path P2 is determined by the controlling signal Va of the multiplexer 430. Referring to FIG. 5A and FIG. 5B. FIG. 5A is a circuit diagram of generating a control signal of a first multiplexer of the invention. FIG. 5B is a circuit diagram of generating a control signal of a second multiplexer of the invention. As indicated in FIG. 5A, the left-hand circuit connects the P type metal oxide semiconductor (MOS) PM0 to the N type metal oxide semiconductor NM0 in serial, and the right-hand circuit connects the P type metal oxide semiconductor PM1 to N type metal oxide semiconductor NM1 in serial. Such structure determines the output voltage Va by programming the N type metal oxide semiconductor NM0 or NM1. When the N type metal oxide semiconductor NM0 is programmed, despite the N type metal oxide semiconductors NM0 and NM1 are respectively connected to a high-voltage terminal Vcc by the gate, the N type metal oxide semiconductor NM0 can not be conducted with the grounding terminal GND because the N type metal oxide semiconductor NM0 is programmed hence having a higher threshold voltage. On the contrary, the N type metal oxide semiconductor NM1 can be conducted with the grounding terminal GND, so the electrical potential of the output voltage Va is the same as that of the grounding terminal GND. As the gate of the P type metal oxide semiconductor PM0 is coupled to the right-hand circuit, the electrical potential of the gate is the same as that of the grounding terminal GND, such that the P type metal oxide semiconductor PM0 is conducted and the electrical potential of the left-hand circuit is the same as that of the high-voltage terminal Vcc. As the gate of the P type metal oxide semiconductor PM1 is coupled to the left-hand circuit, the electrical potential of the gate of the P type metal oxide semiconductor PM1 is the same as that of the high-voltage terminal Vcc, such that the gate of the P type metal oxide semiconductor PM1 shuts the channel to suppress the current for preventing the right-hand circuit from continually generating a current hence avoiding unnecessary loss. Likewise, for the output voltage Va to output the electrical potential of the high-voltage terminal Vcc, the N type metal oxide semiconductor NM1 is programmed.

As indicated in FIG. 5B, the elements of FIG. 5B are the same as that of FIG. 5A but the ways of connection are not the same. Such structure determines the output voltage Va by programming the P type metal oxide semiconductor PM0 or the P type metal oxide semiconductor PM1. For example, when the P type metal oxide semiconductor PM0 is programmed, despite the P type metal oxide semiconductor PM0 and the P type metal oxide semiconductor PM1 are respectively connected to the grounding terminal GND by the gate, the P type metal oxide semiconductor PM0 can not be conducted with the high-voltage terminal Vcc because the P type metal oxide semiconductor PM0 is programmed hence having a higher threshold voltage. On the contrary, the P type metal oxide semiconductor PM1 can be conducted with the high-voltage terminal Vcc, so the electrical potential of the output voltage Va is the same as that of the high-voltage terminal Vcc. As the gate of the N type metal oxide semiconductor NM0 is coupled to the right-hand circuit, the electrical potential of the gate is the same as that of the high-voltage terminal Vcc, such that the N type metal oxide semiconductor NM0 is conducted such that the electrical potential of the left-hand circuit is the same as that of the grounding terminal GND. As the gate of the N type metal oxide semiconductor NM1 is also coupled with the left-hand circuit, the electrical potential of the gate of the N type metal oxide semiconductor NM1 is the same as that of the grounding terminal GND, such that the gate of the N type metal oxide semiconductor NM1 shuts the channel to suppress the current for preventing the right-hand circuit from continually generating a current hence avoiding unnecessary loss. Likewise, for the output voltage Va to output the electrical potential of the grounding terminal GND, the P type metal oxide semiconductor PM1 is programmed.

If the circuit structure of FIG. 5A or FIG. 5B is adopted, by programming various metal oxide semiconductor (MOS) elements, the output voltage Va is controlled to output various electrical potentials, such that the non-volatile memory 400 can output data via different paths.

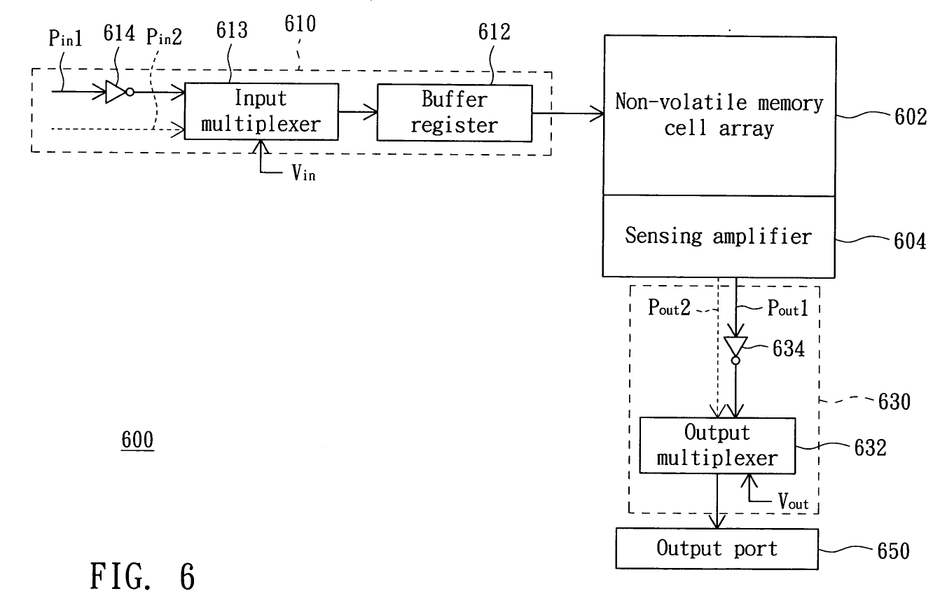

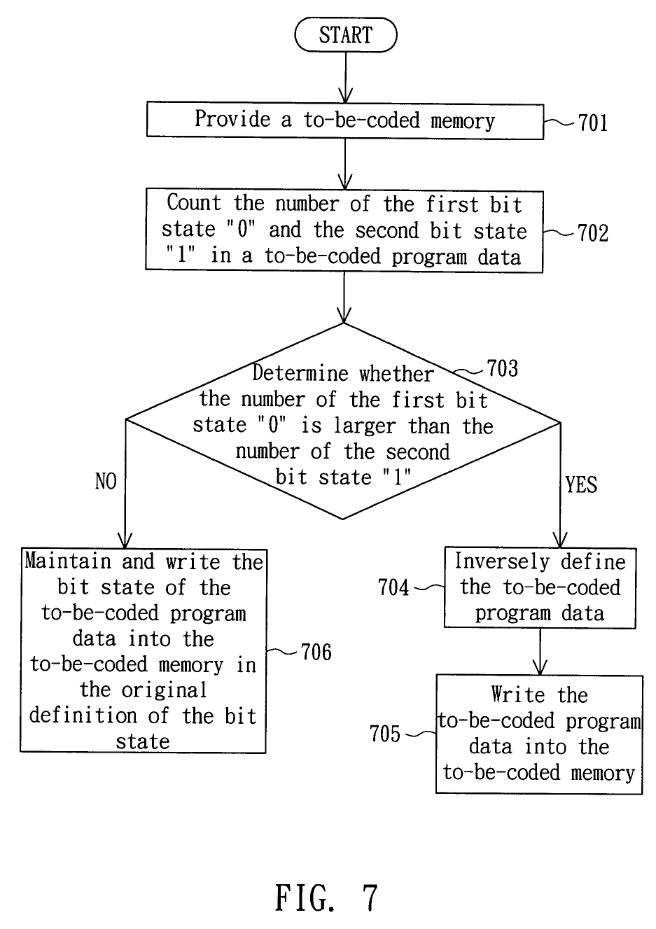

As for the writing and reading method of the one-time program (OTP) memory, the multi-time program (MTP) memory and the flash memory of the invention, referring to FIG. 6, a functional diagram of the writing and reading circuit of a non-volatile memory of the invention is shown. Also referring to FIG. 7, a flowchart of writing a non-volatile memory of the invention is shown. First, the method begins at step 701, a to-be-coded memory 600 is provided. The to-be-coded memory 600 comprises a non-volatile memory cell array 602 and a sensing amplifier 604. The non-volatile memory cell array 602 respectively records a first bit state after the non-volatile memory cell array 602 is programmed and a second bit state before the non-volatile memory cell array 602 is programmed. The first bit state and the second bit state respectively refer to “0” and “1” in the present embodiment of the invention.

Next, the method proceeds to step 702, the number of the first bit state “0” and the second bit state “1” in a to-be-coded program data is counted. Such function can be programmed in a programming language and integrated with the circuit structure of the to-be-coded memory 600.

Then, the method proceeds to step 703, whether the number of the first bit state “0” is larger than the number of the second bit state “1” is determined. If the number of the first bit state “0” is larger than the number of the second bit state “1”, the method proceeds to step 704, the to-be-coded program data is inversely defined. Then, the method proceeds to step 705, the to-be-coded program data is written into the to-be-coded memory 600. In step 703, if the number of the first bit state “0” is smaller than the number of the second bit state “1”, the method proceeds to step 706, the original definition of the bit state is maintained and written into the to-be-coded memory 600.

The data input channel 610 of the to-be-coded memory 600 further comprises an input multiplexer (MUX) such as the input multiplexer 613, which determines whether the written to-be-coded program data needs to be inversely defined according to the number of the first bit state “0” and the number of the second bit state “1” as indicated in step 703. The input multiplexer 613 is controlled by the controlling voltages Vᵢₙ, wherein the controlling voltages Vᵢₙ can be generated by the circuit structure of FIG. 5A or FIG. 5B to determine whether the data channel 710 takes path Pᵢₙ1 or Pᵢₙ2.

If the number of the first bit state “0” is larger than the number of the second bit state “1” in to-be-coded program data, the method proceeds to step 704, the to-be-coded program data is inversely defined by the input inverter 614 of FIG. 6. Then, the method proceeds to step 705, after each set of to-be-coded program data has accumulated a certain amount of writing data via the buffer register 612, the accumulated to-be-coded program data is written into the to-be-coded memory 600 in one time. On the contrary, if the number of the first bit state “0” is smaller than the second bit state “1” in the to-be-coded program data, as indicated in step 706, the original definition of bit state of the to-be-coded program data is maintained and the to-be-coded program data is written into the to-be-coded memory 600.

According to the writing method provided in the present embodiment of the invention, the required time for electrically programming the first bit state “0” is shortened, hence increasing the production efficiency of the memory. Moreover, the present embodiment of the invention further inversely defines the bit state of the remaining memory cells of the non-volatile memory cell array 602 after the to-be-coded program data is written into the to-be-coded memory 600. That means the remaining memory cells having bit state “0” don't need to be electrically programmed so as to save the time for programming. Such function can be achieved by installing an additional input multiplexer for inversely defining the bit state of the remaining memory cells of the entire non-volatile memory cell array 602. As the memory cells not in use must be electrically programmed to the bit state “0” in conventional process, the required time for programming in the present invention is largely shortened if the memory cells are inversely defined. Particularly, if the remaining memory cells occupy a large portion of the non-volatile memory cell array, the required time for manufacturing the memory is further shortened and the production efficiency is even increased.

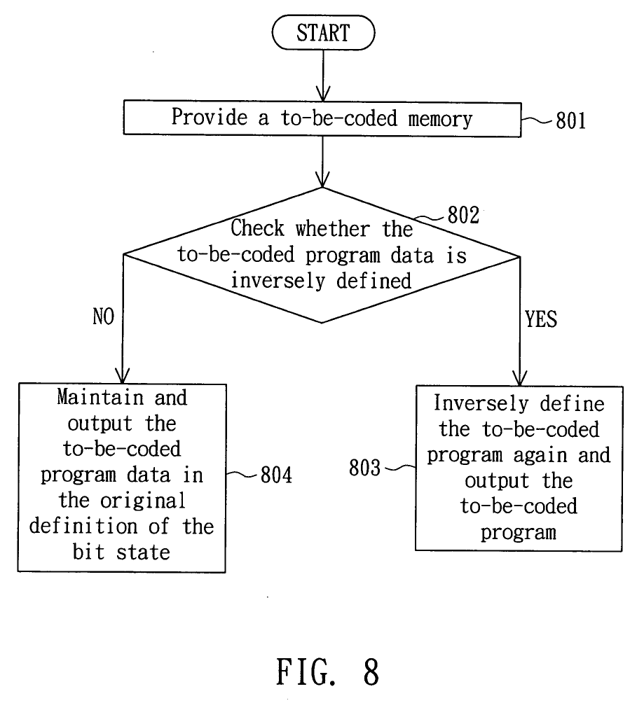

The method for reading the non-volatile memory 600 is stated below. Referring to FIG. 8, a flowchart of reading a non-volatile memory of the invention is shown. Also referring to the designations of the elements of FIG. 6. First, the method begins at step 801, the to-be-coded program data is read from the non-volatile memory cell array 602, then the signal of the read to-be-coded program data is amplified by the sensing amplifier 604 and then outputted thereby.

Next, the method proceeds to step 802, whether the to-be-coded program data is inversely defined is checked. If the to-be-coded program data is inversely defined, then the method proceeds to step 803, the to-be-coded program data is inversely defined again and then outputted. If the to-be-coded program data is not inversely defined, then the method proceeds to step 804, the original definition of the bit state is maintained and the to-be-coded program data is outputted.

In the present embodiment of the invention, the to-be-coded program data is outputted via a data output channel 630. As indicated in step 802, whether the to-be-coded program data is inversely defined and written is checked. Such function can also be programmed with a programming language and integrated with the circuit structure of the to-be-coded memory 600. If the to-be-coded program data is ever inversely defined, then the method proceeds to step 803, the to-be-coded program data is inversely defined again and then outputted to the output port 650. For example, the outputted data taking path Pₒᵤₜ1 is inversely defined by the output inverter 634. If the to-be-coded program data is never inversely defined, then the original definition of bit state of the to-be-coded program data is maintained and the to-be-coded program data is outputted to the output port 650. For example, the data output channel 630 takes path Pₒᵤₜ2. The selection of the path is determined by the output multiplexer 632 of the data channel 630. The controlling voltages Vₒᵤₜ for the output multiplexer 632 can be generated by the circuit of FIG. 5A and FIG. 5B. Moreover, if the remaining memory cells of the to-be-coded memory 600 have been inversely defined, then the bit state of the remaining memory cells of the non-volatile memory cell array 602 is need to be inversely defined again and then outputted. Such function can be achieved by installing another set of output multiplexer for inversely defining and outputting the bit state of the remaining memory cells of the entire non-volatile memory cell array 602. The outputted data will be the same as the original to-be-coded program data. Whether the to-be-coded program data needs to be inversely defined again and outputted depends upon whether the to-be-coded program data is ever inversely defined.

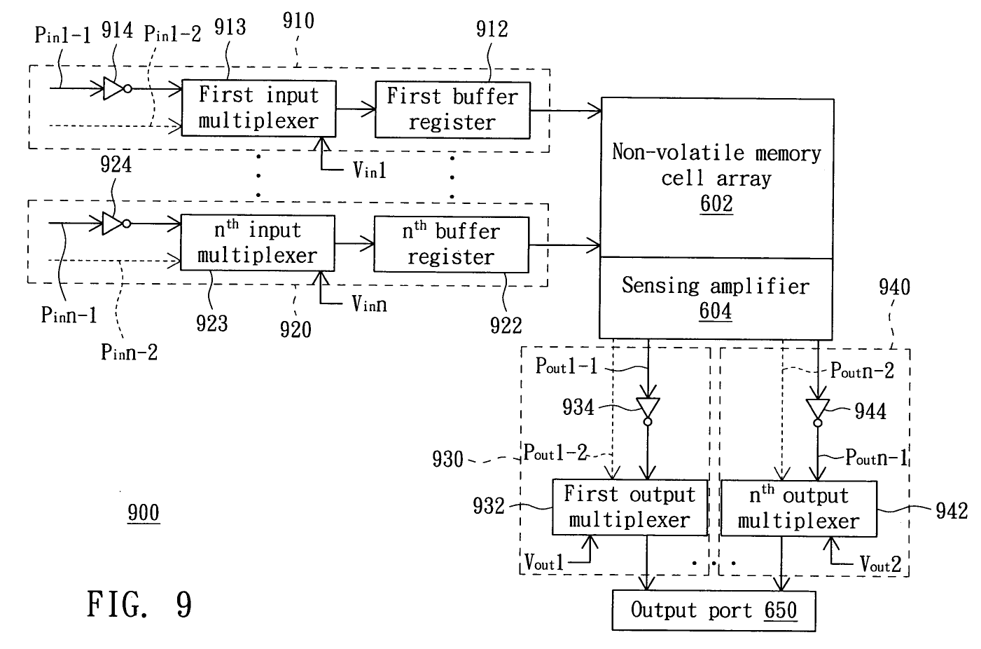

referring to FIG. 9, another functional diagram of the writing and reading circuit of a non-volatile memory of the invention is shown. The flowcharts of writing and reading the another non-volatile memory is the same as those of FIG. 7 and FIG. 8, respectively. The non-volatile memory 900 differs with the non-volatile memory 600 mainly in that the non-volatile memory 900 has multi-data input channels and multi-data output channels. Other elements having the same functions still use the same numbering.

In the non-volatile memory 900, the to-be-coded program data is further divided into n sets including a first set to an n^{th} set. For example, in the present embodiment of the invention, the to-be-coded memory 900 further comprises n data input channels, and the to-be-coded program data is divided into a first set to an n^{th} set according to the data input channels that the to-be-coded program data has passed through. For simplification, only the first set of data input channel 910 and the n^{th} set of data input channel 920 are illustrated in FIG. 9. As indicated in step 702, each set of data channel counts the number of the first bit state “0” and the second bit state “1” from the first set of to-be-coded program data to the n^{th} set of to-be-coded program data passing through the first data channel 910 to the n^{th} data channel 920 respectively. Each data input channel of the to-be-coded memory 900 further comprises an input multiplexer (MUX) such as the first input multiplexer 913 to the n^{th} input multiplexer 923 of FIG. 9, wherein the input multiplexer determines whether the written to-be-coded program data needs to be inversely defined according to the number of the first bit state “0” and the number of the second bit state “1” as indicated in step 703. The first input multiplexer 913 to the n^{th} input multiplexer 923 are controlled by the controlling voltages Vᵢₙ1 to Vᵢₙn respectively, wherein the controlling voltages Vᵢₙ1 to Vᵢₙn can be generated by the circuit structure of FIG. 5A or FIG. 5B to determine whether the data channel 910 takes path Pᵢₙ1_1 or Pᵢₙ1_2 and whether the data channel 920 takes path Pᵢₙn_1 or Pᵢₙn_2.

If the number of the first bit state “0” is larger than the number of the second bit state “1” in any set of to-be-coded program data, the method proceeds to step 704, the any set of the to-be-coded program data having more first bit state “0” is inversely defined by the corresponding inverter among the first input inverter 914 to the nth input inverter 924 of FIG. 9. Then, the method proceeds to step 705, after each set of to-be-coded program data has accumulated a certain amount of writing data via the first buffer register 912 to the n^{th} buffer register 922, the accumulated to-be-coded program data is written into the to-be-coded memory 900 in one time. On the contrary, if the number of the first bit state “0” is smaller than the second bit state “1” in any set of to-be-coded program data, as indicated in step 706, the original definition of bit state of the any set of to-be-coded program data is maintained and the any set of to-be-coded program data is written into the to-be-coded memory 900.

In the present embodiment of the invention, if the to-be-coded program data is inputted via n sets of data input channels, then the to-be-coded program data has to be outputted via n sets of data output channels. For simplification, only the first set of data output channel 930 and the n^{th} set of data output channel 940 are illustrated in FIG. 9. As indicated in step 802, whether the first set of to-be-coded program data to the n^{th} set of to-be-coded program data is ever inversely defined and written is checked. Such function can also be programmed with a programming language and integrated with the circuit structure of the to-be-coded memory 900. If any set of to-be-coded program data is ever inversely defined, then the method proceeds to step 803, the any inversely defined set of the to-be-coded program data is inversely defined again and then outputted to the output port 650. For example, the first set of data output channel 930 and the n^{th} set of data output channel 940 take path Pₒᵤₜ1_1 and Pₒᵤₜn_1 and are inversely defined by the first output inverter 934 and the n^{th} output inverter 944 respectively. If no set of t to-be-coded program data is ever inversely defined, then the original definition of bit state of each set of the to-be-coded program data is maintained and the to-be-coded program data is outputted to the output port 650. For example, the first set of data output channel 930 and the n^{th} set of data output channel 940 take path Pₒᵤₜ1_2 and Pₒᵤₜn_2 respectively. The selection of the path is determined by the output multiplexer of each set of data channel such as the first output multiplexer 932 of the data output channel 930, and the n^{th} output multiplexer 942 of data output channel 940 respectively. The controlling voltages Vₒᵤₜ1 and Vₒᵤₜn for the first output multiplexer 932 and the n^{th} output multiplexer 942 can be generated by the circuit of FIG. 5A of FIG. 5B. Moreover, if n is equal to 1, the to-be-coded memory 900 is the same as the to be-coded memory 600.

According to the method of manufacturing non-volatile memory disclosed in the above embodiments of the invention, when the number of the to-be-coded cells requiring ion-implantation is larger than the number of the to-be-coded cells not requiring ion-implantation, ions are implanted into the to-be-coded cell originally not requiring ion-implantation, such that the to-be-coded cells record the bit state opposite to the original definition of the bit state in the to-be-coded program. Next, the to-be-coded memory is inversely defined to obtain a memory having the same bit state as that of the to-be-coded program. As the number of the exposed to-be-coded cells is reduced, the failure rate of implantation caused by the obstruction by a dropped-in object or the misalignment of an ion-implanting resist layer is reduced. Therefore, without adding additional steps or significantly changing the manufacturing process, the invention is capable of reducing the occurrences of obstruction caused by a dropped-in object or the misalignment of an ion-implanting resist layer, hence increasing the yielding rate of the non-volatile memory. The method of writing and reading a non-volatile memory disclosed in the invention largely shortens the required time for writing (i.e., electrically programing) the non-volatile memory and increases the production efficiency of the memory.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of manufacturing a non-volatile memory, comprising:
(a) providing a to-be-coded memory having a plurality of to-be-coded cells arranged in an array;
(b) forming an implanting resist layer on the to-be-coded memory;
(c) disposing a mask on the to-be-coded memory, wherein the mask has a plurality of opening, the partial to-be-coded cells under the openings are defined as a plurality of second to-be-coded cells, the remaining to-be-coded cells are defined as a plurality of first to-be-coded cells, and the number of the second to-be-coded cells is less than the number of the first to-be-coded cells;
(d) defining a pattern on the implanting resist layer according to the mask to form a patterned implanting resist layer, the patterned implanting resist layer have a plurality of coding holes for exposing the second to-be-coded cells;
(e) ion-implanting the second to-be-coded cells such that the first to-be-coded cells are defined as a plurality of first cells, and the second to-be-coded cells are defined as a plurality of second cells, the first cells and the second cells recording a second bit state and a first bit state respectively; and
(f) inversely defining the to-be-coded memory, such that the first cells and the second cells record the first bit state and the second bit state respectively.

2. The manufacturing method according to claim 1, wherein prior to the step (f) further comprising:
(g) comparing a first current value and a second current value respectively passing through the first cells and the second cells when the first cells and the second cells are turned on with a reference current value to define the first cells and the second cells respectively to record a second bit state and a first bit state.

3. The manufacturing method according to claim 2, wherein in step (g), the first current value is larger than the reference current value, and the second current value is smaller than the reference current value.

4. The manufacturing method according to claim 3, wherein in step (f), the first cell is defined to record the first bit state if the first current value is larger than the reference current value, and the second cell is defined to record the second bit state if the second current value is smaller than the reference current value.

5. The manufacturing method according to claim 4, wherein the first bit state is denoted by 0, and the second bit state is denoted by 1.

6. The manufacturing method according to claim 4, wherein the first bit state is denoted by 1, and the second bit state is denoted by 0.

7. The manufacturing method according to claim 2, wherein in step (g), the first current value is smaller than the reference current value, and the second current value is larger than the reference current value.

8. The manufacturing method according to claim 7, wherein in step (f), the first cell is defined to record the first bit state if the first current value is smaller than the reference current value, and the second cell is defined to record the second bit state if the second current value is larger than the reference current value.

9. The manufacturing method according to claim 8, wherein the first bit state is denoted by 0, and the second bit state is denoted by 1.

10. The manufacturing method according to claim 8, wherein the first bit state is denoted by 1, and the second bit state is denoted by 0.

11. The manufacturing method according to claim 1, further comprising:
counting the number of a first bit state and a second bit state in a to-be-coded program.

12. The manufacturing method according to claim 1, wherein in step (e), the implanted material is made of boron.

13. A method of writing a non-volatile memory, comprising:
(a) providing a to-be-coded memory, the memory cells of the to-be-coded memory respectively record a first bit state after the to-be-coded memory is programmed, and a second bit state before the to-be-coded memory is programmed;
(b) counting the number of the first bit state and the second bit state in a to-be-coded program data;
(c) inversely defining the to-be-coded program data if the number of the first bit state is larger than the number of the second bit state; and
(d) writing the to-be-coded program data into the to-be-coded memory.

14. The writing method according to claim 13, further comprising:
(e) maintaining and writing the to-be-coded program data in the original definition of the bit state into the to-be-coded memory if the number of the first bit state is smaller than the number of the second bit state.

15. The writing method according to claim 13, wherein the to-be-coded program data is further divided into n sets including a first set to an n^{th} set, the step (b) further comprises:
(b1) counting the number of the first bit state and the number of and the second bit state from the first set of to-be-coded program data to the n^{th} set of to-be-coded program data respectively.

16. The writing method according to claim 15, wherein, the step (c) further comprises:
(c1) inversely defining any set of to-be-coded program data if the number of the first bit state is larger than the number of the second bit state in the any set of to-be-coded program data.

17. The writing method according to claim 15, wherein the to-be-coded memory further comprises n data input channels, and the to-be-coded program data is divided into the first set to the n^{th} set according to the data input channels that the to-be-coded program data has passed through.

18. The writing method according to claim 15, further comprising:
(f) maintaining and writing any set of to-be-coded program data in the original definition of the bit state into the to-be-coded memory if the number of the first bit state is smaller than the number of the second bit state in the any set of to-be-coded program data.

19. The writing method according to claim 13, further comprising:
(g) inversely defining the bit state of the remaining memory cells after the to-be-coded program data is written into the to-be-coded memory.

20. The writing method according to claim 13, wherein the to-be-coded memory further comprises at least one input multiplexer (MUX) for determining whether the written to-be-coded program data need to be inversely defined according to the number of the first bit state and the number of the second bit state.

21. A method of reading non-volatile memory for reading the to-be-coded memory according to claim 13, comprising:
(a) reading the to-be-coded program data;
(b) checking whether the to-be-coded program data is inversely defined; and
(c) inversely defining the to-be-coded program again and outputting the to-be-coded program if the to-be-coded program data is inversely defined.

22. The reading method according to claim 21, further comprising:
(d) maintaining and outputting the to-be-coded program data in the original definition of the bit state if the to-be-coded program data is not inversely defined.

23. The reading method according to claim 21, wherein the to-be-coded program data is further divided into n sets including a first set to an n^{th} set, the step (b) further comprises:
(b1) checking whether any set of to-be-coded program data is inversely defined;
wherein, the step (c) further comprises:
(c1) inversely defining the any set of to-be-coded program data again and outputting the any set of to-be-coded program data if the any set of to-be-coded program data data is inversely defined.

24. The reading method according to claim 21, further comprising:
(e) maintaining and outputting each set of to-be-coded program data in the original definition of bit state if no set of to-be-coded program data is inversely defined.

25. The reading method according to claim 21, further comprising:
(f) inversely defining the bit state of the remaining memory cells of the to-be-coded memory again after the to-be-coded program data is written into the to-be-coded memory.

26. The reading method according to claim 21, wherein the to-be-coded memory further comprises at least one output multiplexer (MUX) for determining whether the to-be-coded program data need to be inversely defined again according to whether the to-be-coded program data is inversely defined.
